(19) United States
(12) Patent Application Publication
(10) Pub. No.: US 2007/0069356 A1
(43) Pub. Date: Mar. 29, 2007

(54) Optical parts cap and method of manufacturing the same

(75) Inventors: Toshihisa Yoda, Nagano (JP); Kenji Kawamura, Nagano (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: SHINKO ELECTRIC INDUSTRIES, CO., LTD, Nagano-shi (JP)

(21) Appl. No.: 11/501,698

(22) Filed: Aug. 10, 2006

(30) Foreign Application Priority Data
Sep. 29, 2005 (JP) 2005-283689

(51) Int. Cl. H01L 23/02

(52) U.S. Cl. 257/680

(57) ABSTRACT

An optical parts cap of the present invention includes a metal frame having an upper frame portion in which an opening portion is provided to a center portion and an upright frame portion provided to be connected to a lower peripheral portion of the upper frame portion, the metal frame in which a housing portion is provided in an inside of the metal frame by the upright frame portion, a reflection preventing layer formed on an outer surface and an inner surface of the metal frame respectively, and a glass provided to the housing portion of the metal frame, the reflection preventing layer is formed of either the metal oxide layer or the metal plating layer.

### CROSS-REFERENCE TO RELATED APPLICATIONS

This application is based on and claims priority of Japanese Patent Application No. 2005-283689 filed on Sep. 29, 2005, the entire contents of which are incorporated herein by reference.

### BACKGROUND OF THE INVENTION

1. Field of the Invention

The present invention relates to an optical parts cap and a method of manufacturing the same and, more particularly, an optical parts cap applicable to a cap for an optical parts that reflects a light from a light source to project an image, and a method of manufacturing the same.

2. Description of the Related Art

The DLP (Digital Light Processing) technology to project an image by reflecting a light emitted from a light source by an optical parts has been developed in the prior art. As such optical parts, there is the DMD (Digital Micromirror Device) in which a great number of mirrors each several μm square are arranged on the silicon substrate to reflect a light.

The DMD is mounted in a condition that this DMD is hermetically sealed by the cap. A black frame layer (chromium layer) is provided to this cap not to reflect unnecessarily a light from its peripheral portion. As shown in FIG. 1, in the prior art, a cap 100 is constructed by a ring-like frame portion 110 in which an opening portion 110x is provided in a center portion, a transparent glass 120 provided in the opening portion 110x, and a black frame layer 130 formed of a chromium layer and provided on the lower peripheral side of the frame portion 110. Also, a DMD 300 is mounted in a cavity 200x provided to a center portion of a substrate 200, and then the cap 100 is joined to a projection portion 210 in a peripheral portion of the substrate 200 to hermetically seal this DMD 300. Accordingly, a reflection of a light from a light source and a reflected light from the DMD 300 is suppressed in a peripheral portion of the cap 100, so that only a light transmitted through a light transmission window in the inside of the black frame layer 130 is emitted to the outside.

In the method of manufacturing the cap 100 in the prior art, first, the chromium layer is formed on the lower side of the frame portion 110 in which the glass 120 is provided in the opening portion 110x by the mask vapor deposition. Then, the chromium layer is patterned by the photolithography and the etching, and thus a light transmission window is provided in its center portion and the black frame layer 130 is formed selectively on the peripheral side.

Also, the DMD package having such a structure that the glass window is provided to the top side of the housing and the chromium layer is patterned on the peripheral portion of the glass window is set forth in Patent Literature 1 (Patent Application Publication (KOHYO) 2005-512114).

However, in the prior art, since the step of depositing the chromium layer and the step of patterning the same (the lithography and the etching) are needed to form the black frame layer, there is such a problem that an increase of a production cost is brought about. Also, since a relatively high pattern accuracy is required of the light transmission window of the cap, the complicated process management is required in patterning the chromium layer. In addition, in some cases such disadvantages are caused that the jagged pattern is formed in etching the chromium layer, and the like.

Under these circumstances, a method of manufacturing the optical parts cap by a simple method not to use the chromium layer is desired earnestly.

### SUMMARY OF THE INVENTION

It is an object of the present invention to provide an optical parts cap manufactured easily at a low cost without film formation and patterning of a chromium layer, and a method of manufacturing the same.

The present invention is concerned with an optical parts cap, which comprises a metal frame including an upper frame portion in which an opening portion is provided in a center portion and an upright frame portion provided to be connected to a lower peripheral portion of the upper frame portion, the metal frame in which a housing portion is provided in an inside by the upright frame portion, a reflection preventing layer formed on an outer surface and an inner surface of the metal frame respectively; and a glass provided to the housing portion of the metal frame.

The optical parts cap of the present invention is obtained by forming a ring-like metal frame in which an opening portion is provided to a center portion of which and a housing portion is provided in an inside of which, by means of the stamping, or the like, and then forming a reflection preventing layer showing black or gray on an outer surface and an inner surface of the metal frame.

In one preferred mode of the present invention, first, a blackish metal oxide layer (a kovar oxide layer, or the like) is formed by oxidizing the metal frame, and then the glass is deposited into the housing portion of the metal frame. Then, the metal oxide layer on the outer exposed portion that does not contact the glass in the metal frame is removed, and then the blackish metal plating layer, ink, or the like functioning as the reflection preventing layer is formed on the outer surface of the metal frame.

Accordingly, a first reflection preventing layer made of the metal oxide layer is formed on an inner surface of the metal frame, and a second reflection preventing layer made of the metal plating layer, the ink, or the like is formed on an outer surface of the metal frame. Otherwise, the metal oxide layer formed on the overall surface of the metal frame can be utilized as the reflection preventing layer as it is.

In this manner, in the present invention, since the approach of forming the reflection preventing layer by applying the darkening process to the inner surface and the outer surface of the metal frame is employed, the step of forming the chromium layer and the step of patterning it (the photolithography and the etching) leading to an increase in cost are not needed. Therefore, a remarkably lower cost can be attained rather than the prior art.

Also, in the present invention, the light transmission window is defined by the opening portion, which is formed by the stamping with high machining accuracy, in the metal frame. Therefore, the optical parts cap having the light transmission window whose pattern accuracy is can be manufactured stably with good yield not to execute the complicated process management.

As described above, the optical parts cap of the present invention can be manufactured at a low cost by a very simple method.

### BRIEF DESCRIPTION OF THE DRAWINGS

FIG. 1 is a sectional view showing an optical parts cap in the prior art;

FIGS. 2A to 2F are sectional views showing a method of manufacturing an optical parts cap according to a first embodiment of the present invention;

FIG. 3 is a sectional view showing the optical parts cap according to the first embodiment of the present invention, which is equivalent to a sectional view taken along I-I in FIG. 4;

FIG. 4 is a plan view showing the optical parts cap according to the first embodiment of the present invention;

FIG. 5 is a sectional view showing an example in which the optical parts cap according to the first embodiment of the present invention is applied to a cap for an optical parts;

FIG. 6 is a view where a reflectance of a darkening layer made of a rough Ni plating layer and a kovar oxide layer used in the embodiment of the present invention and a reflectance of a chromium layer used in the prior art are compared mutually; and

FIGS. 7A to 7E are sectional views showing a method of manufacturing an optical parts cap according to a second embodiment of the present invention.

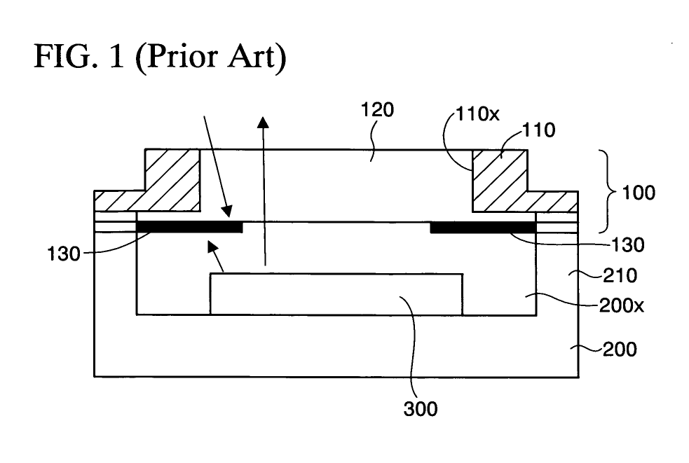

### DETAILED DESCRIPTION OF THE PREFERRED EMBODIMENTS

Embodiments of the present invention will be explained with reference to the accompanying drawings hereinafter.

### First Embodiment

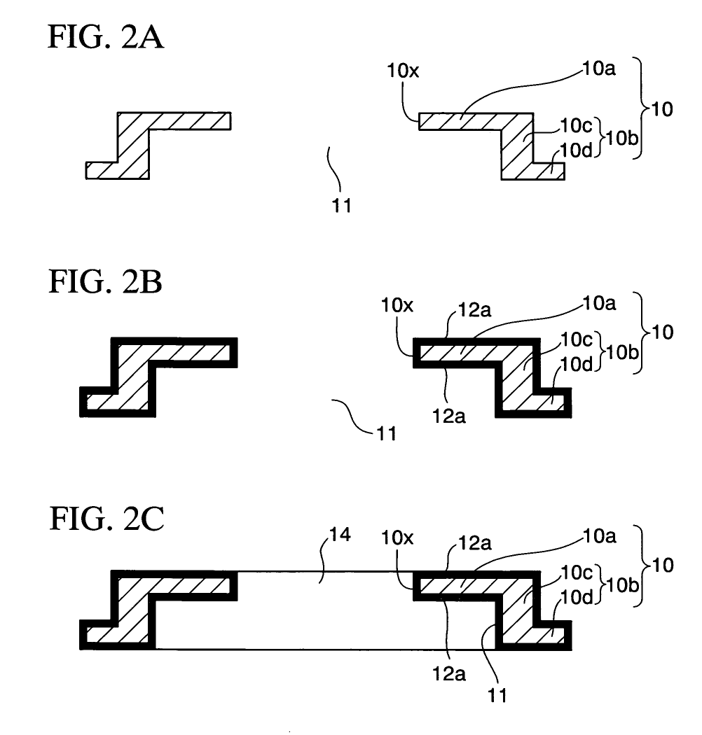

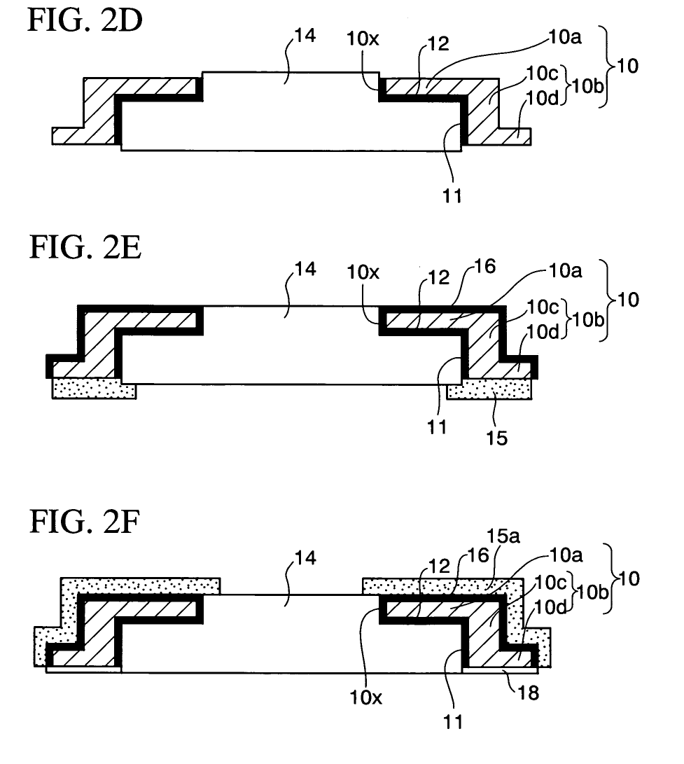

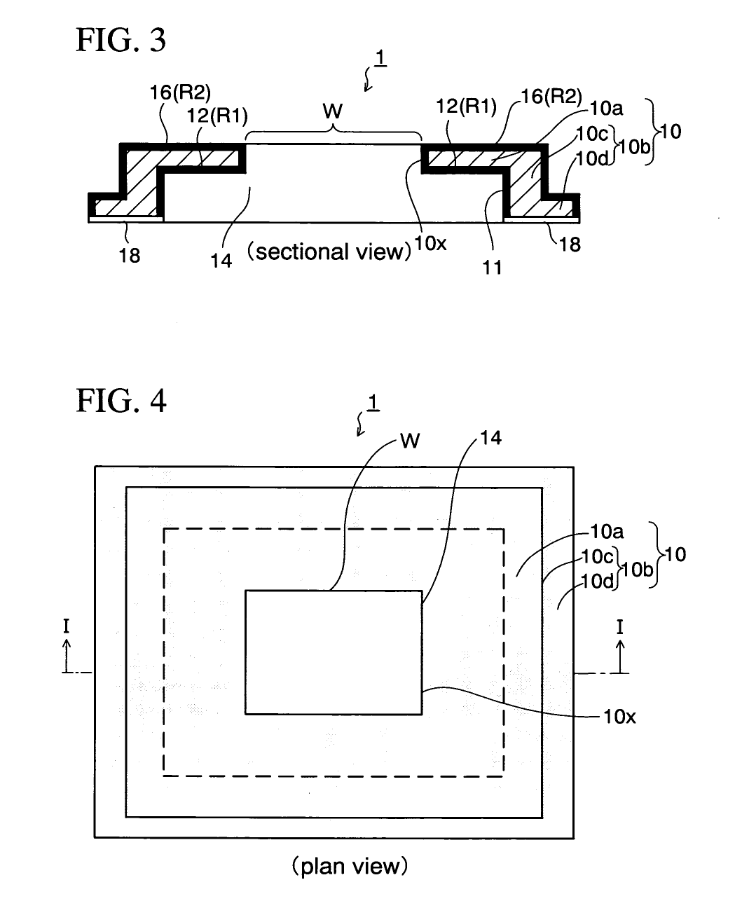

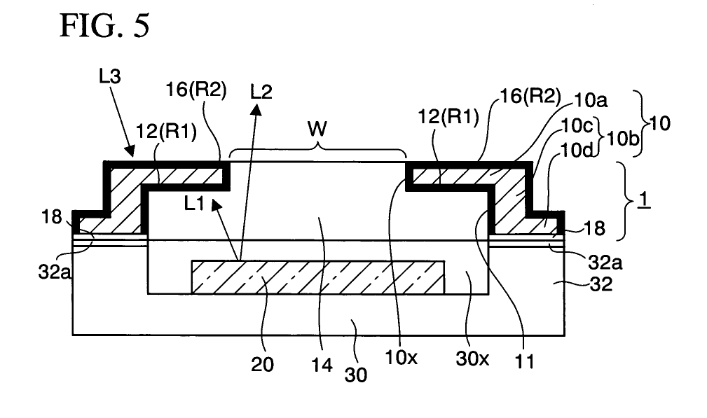

FIGS. 2A to 2F are sectional views showing a method of manufacturing an optical parts cap according to a first embodiment of the present invention, FIG. 3 and FIG. 4 are a sectional view and a plan view showing the optical parts cap of the same, and FIG. 5 is a sectional view showing an example in which the optical parts cap of the same is applied to a cap for an optical parts.

In the method of manufacturing an optical parts cap according to a first embodiment, as shown in FIG. 2A, first, a ring-like metal frame 10 in which an opening portion 10x is provided in a center portion is formed by applying the stamping or the cutting to a metal plate. The metal frame 10 is constructed by a ring-like upper frame portion 10a in which the opening portion 10x is provided in a center portion, and a ring-like upright frame portion 10b provided to be connected to a lower peripheral portion of the upper frame portion 10a. The upright frame portion 10b is constructed by a ring-like side wall portion 10c, and a ring-like lower frame portion 10d extended from a lower peripheral portion of the side wall portion 10c to the outside. The metal frame 10 is formed to have a housing portion 11 in an inner portion by providing the upright frame portion 10b.

Then, as shown in FIG. 2B, the metal frame 10 is oxidized in an oxygen atmosphere by executing a heat treatment at 700 to 800° C. Thus, a metal oxide layer 12a is formed on a surface of the metal frame 10 to darken. As a concrete example, the metal frame 10 is formed of kovar (an iron (Fe)-nickel (Ni)-cobalt (Co) alloy), and then a kovar oxide layer of 10 to 20 μm thickness is formed by heating/oxidizing the kovar in an oxygen atmosphere at 700° C. for 43 minute to darken. As the material of the metal frame 10, a Fe—Ni alloy, or the like may be employed except kovar. Here, the darkening means that a surface color of the material is changed into a color such as gray or black that can prevent a light reflection.

Then, as shown in FIG. 2C, a transparent glass 14 is arranged to correspond to the housing portion 11 of the metal frame 10. Then, this glass 14 is deposited onto the housing portion 11 of the metal frame 10 by executing the heat treatment at about 900° C.

Then, as shown in FIG. 2D, the outer metal oxide layer 12a that does not contact the glass 14 of the metal frame 10 is removed selectively by the wet etching to expose the metal (kovar) of the metal frame 10. Thus, the metal oxide layer 12a left on an inner surface (portion contacting the glass 14) of the metal frame 10 constitutes an inner darkening layer 12. The metal oxide layer 12a left on the inner surface of the metal frame 10 is used not only as a reflection preventing layer but also as an adhesive layer that is used to deposit the glass 14 onto the metal frame 10.

Then, as shown in FIG. 2E, a protection film 15 acting as the plating resist is pasted on a lower surface of the upright frame portion 10b of the metal frame 10. Then, an outer darkening layer 16 is formed by applying a nickel (Ni) plating to the exposed portion on the outside of the metal frame 10 by means of the electroplating or the electroless plating. Then, the protection film 15 is removed.

As a preferred example of the Ni plating conditions applied to darken the outside of the metal frame 10, a plating solution (pH: 4.5 to 5.5, temperature: ordinary temperature (25° C.)) containing nickel chloride (75 g/l), sodium thiocyanate (15 g/l), and ammonium chloride (30 g/l) is used, and a cathode current density of 1 to 3 A/cm², and a processing time of 15 sec to 30 min are employed as the conditions. By employing such electroplating conditions, a Ni plating layer whose film thickness is 2 to 10 μm and whose surface is roughened is formed. This Ni plating layer can be used as the darkening layer that shows black or gray.

In this case, as the metal plating that can be used as the darkening layer (reflection preventing layer), there are a tin (Sn)-nickel (Ni) alloy (film thickness: 0.01 to 0.1 μm), a zinc (Zn)-nickel (Ni) alloy (film thickness: 0.01 to 0.1 μm), a ruthenium (Ru) (film thickness: 0.1 to 0.5 μm), a black nickel (Ni)-phosphorus (P) alloy (film thickness: 2 to 6 μm), a black palladium (Pd) (film thickness: 0.1 to 0.5 μm), etc. in addition to Ni.

Then, as shown in FIG. 2F, a protection film 15a for covering the outer darkening layer 16 formed on the metal frame 10 is pasted. Then, a joining portion 18 is formed by forming a gold (Au) layer on a lower surface of the upright frame portion 10b of the metal frame 10 by means of the electroplating or the electroless plating. Then, the protection film 15a is removed.

Accordingly, as shown in FIG. 3 and FIG. 4, an optical parts cap 1 of the present embodiment is obtained. The optical parts cap 1 of the present embodiment is basically constructed by the ring-like metal frame 10 in which the opening portion 10x is provided in the center portion and the housing portion 11 is provided in the inside, and the transparent glass 14 provided into the housing portion 11. Also, the opening portion 10x of the metal frame 10 acts as a light transmission window W. The metal frame 10 is constructed by the ring-like upper frame portion 10a, and the ring-like upright frame portion 10b provided to be connected to the lower peripheral portion of the upper frame portion 10a.

The inner darkening layer 12 obtained by oxidizing the metal frame 10 (kovar) is provided to the inner surface of the metal frame 10, and this layer acts as a first reflection preventing layer R1. The outer darkening layer 16 formed of the rough Ni plating layer is provided to the outer surface of the metal frame 10, and this layer acts as a second reflection preventing layer R2. The joining portion 18 formed of the Au layer is provided on the lower surface of the upright frame portion 10b of the metal frame 10.

In the above mode, the outer darkening layer 16 (second reflection preventing layer R2) is formed by applying the Ni plating to the outer surface of the metal frame 10. But the second reflection preventing layer R2 may be formed by forming a black ink (carbon black, or the like) by means of the ink jet method, the screen printing, the spray, or the like and darkening it. In addition, various methods may be employed if the darkening process gives gray to black acting as the reflection preventing layer.

Also, the lower frame portion 10d of the upright frame portion 10b is not always provided. The joining portion 18 may be formed by increasing a thickness of the side wall portion 10c.

Next, an example in which the optical parts cap 1 of the present embodiment is applied as a cap for DMD is shown hereunder. The DMD is the optical parts that is constructed by arranging a great number of mirrors each several Am square on the silicon substrate, and can project the image on a screen by reflecting a light from a light source. As shown in FIG. 5, a substrate 30 on which a DMD 20 is mounted is made of the ceramic, and a cavity 30x is provided in the center portion by forming a projection portion 32 onto the peripheral portion. A joining portion 32a formed of the Au layer is provided to an upper surface of the projection portion 32. Then, the DMD 20 is mounted in the cavity 30x of the substrate 30.

The joining portion 18 (Au layer) of the optical parts cap 1 of the present embodiment is joined to the joining portion 32a (Au layer) of the projection portion 32 of the substrate 30, on which such DMD 20 is mounted, by the resistance welding. Accordingly, the DMD 20 is hermetically sealed in the cavity 30x of the substrate 30.

Also, a light from a light source is transmitted through the light transmission window W and then reflected by the DMD 20. Then, a reflected light is transmitted through the light transmission window W and then projected onto a screen to form the image. In the optical parts cap 1 of the present embodiment, the first and second reflection preventing layers R1, R2 are provided to the inner surface and the outer surface of the metal frame 10 respectively. For this reason, a reflected light L1 from the peripheral portion, which is not transmitted through the light transmission window W, out of the reflected light from the DMD 20 is absorbed by the first reflection preventing layer R1 on the inner surface of the metal frame 10. Thus, a light reflection from the peripheral portion of the cap can be suppressed. Therefore, only a reflected light L2 which is transmitted through the light transmission window W is emitted to the outside.

Also, an incident light L3 incident on the outer surface of the metal frame 10 out of a light from a light source is absorbed by the second reflection preventing layer R2 on the outer surface of the metal frame 10. Thus, it can be prevented that an unnecessary reflected light is reflected to the screen side.

In this manner, in the optical parts cap 1 of the present embodiment, the first and second reflection preventing layers R1, R2 are provided to the inner surface and the outer surface of the metal frame 10 respectively. Therefore, since an unnecessary light from the DMD 20 and the outside can be absorbed effectively, the display characteristic of the image obtained by the light reflection from the DMD 20 can be improved.

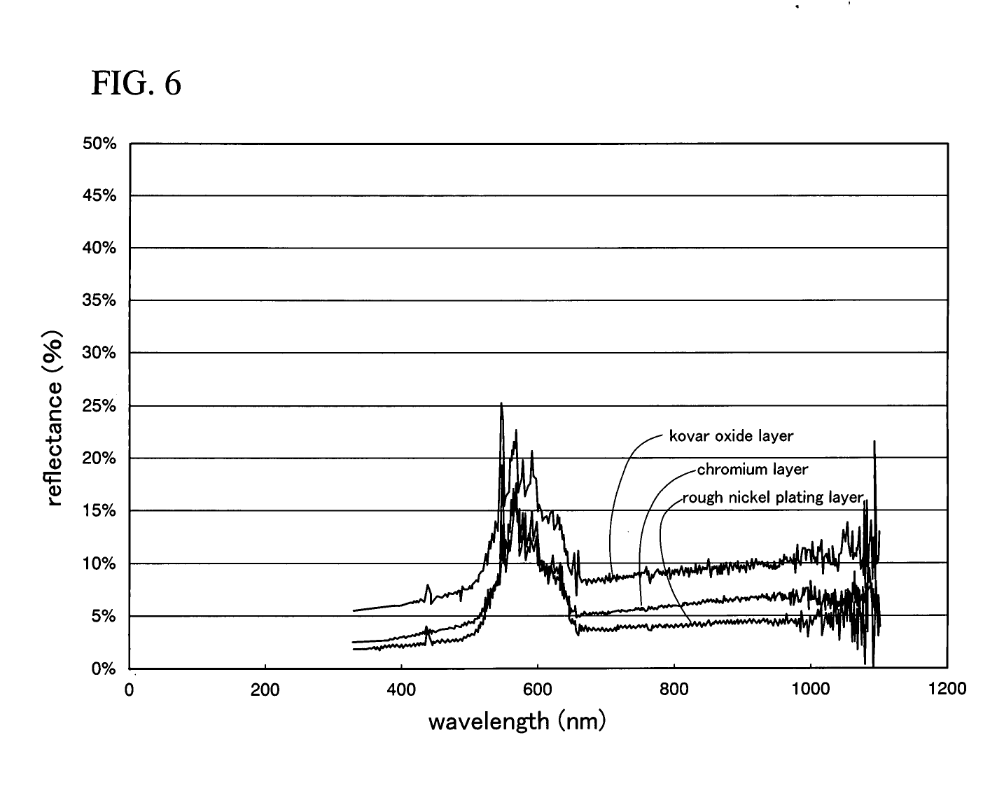

The inventors of this application compared a reflectance of the darkening layer made of the rough Ni plating layer and the kovar oxide layer used in the present embodiment and a reflectance of the chromium layer used in the prior art to examine them. The results are shown in FIG. 6. The light reflection characteristics required for the optical parts cap such as the DMD, or the like are that the reflection can be satisfactorily suppressed in a visible light range (400 to 700 nm) and a reflectance around 400 nm is 10% or less.

As shown in FIG. 6, a reflectance of the rough Ni plating layer of the present embodiment is 20% or less (5% or less around 400 nm) in a band of 400 to 700 nm, which is equivalent to or less than a reflectance of the chromium layer in the prior art. Also, a reflectance of the kovar oxide layer of the present embodiment is 25% or less (10% or less around 400 nm) in a band of 400 to 700 nm, which is slightly higher than a reflectance of the chromium layer in the prior art but has the reflecting characteristics that can be used satisfactorily as the reflection preventing layer.

In this manner, it is understood that the darkening layer made of the rough Ni plating layer and the kovar oxide layer and used in the present embodiment can satisfy the specifications of the light reflection characteristics and is suited for the reflection preventing layer of the optical parts cap such as DMD, or the like.

Also, from a viewpoint of manufacturing the optical parts cap 1 of the present embodiment, the step of depositing the chromium layer and the step of patterning the same (the photolithography and the etching) are not needed unlike the prior art, and the metal oxide layer 12a formed on the inner surface of the metal frame 10 is used as the first reflection preventing layer R1 and also the metal plating layer, or the like formed on the outer surface of the metal frame 10 is used as the second reflection preventing layer R2.

In this manner, the first and second reflection preventing layers R1, R2 can be formed easily to the inner surface and the outer surface of the metal frame 10 respectively by oxidizing the metal frame 10 or applying the metal plating to the metal frame 10. Therefore, a reduction in cost can be achieved considerably in contrast to the prior art.

Also, in the prior art, the light transmission window is defined by pattering the opening in the chromium layer by the photolithography and the etching. Therefore, the complicated process management is required to form the light transmission window with desired pattern accuracy and also such a disadvantage is caused that the jagged patterns are formed, as the case may be, so that sometimes the desired specifications cannot be satisfied.

However, in the present embodiment, the light transmission window W is defined by the opening portion 10x of the metal frame 10 that can be formed by the stamping with high precision. Therefore, the light transmission window W can be formed stably with good precision rather than the prior art. In addition, the metal oxide layer 12 and the metal plating layer are formed on the metal frame 10 in a self-aligned manner as the first and second reflection preventing layers R1, R2. Therefore, the first and second reflection preventing layers R1, R2 can also be formed with high precision.

### Second Embodiment

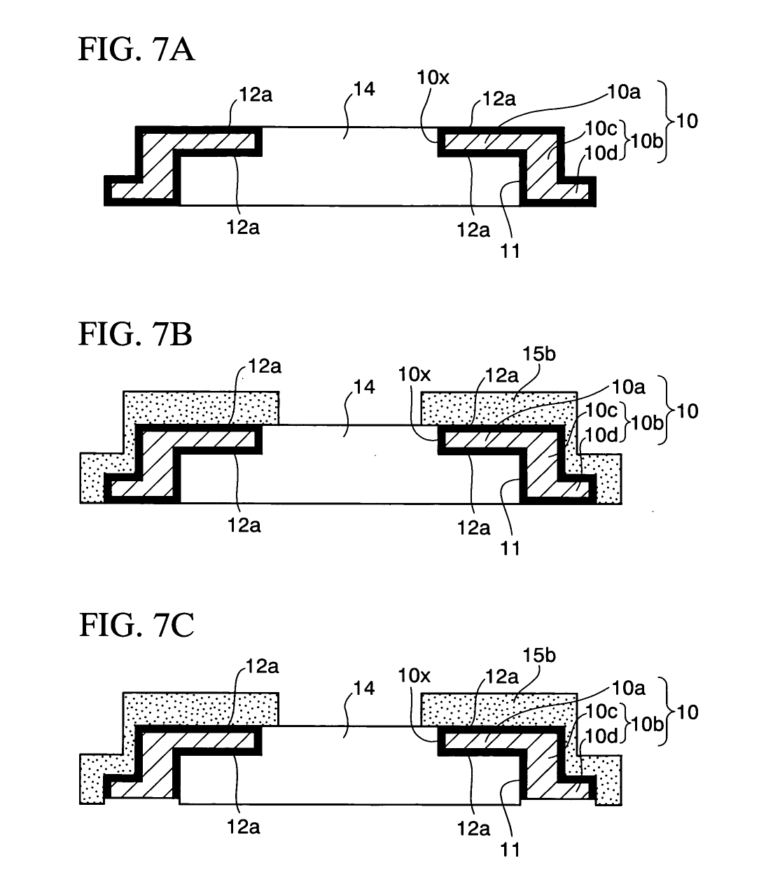

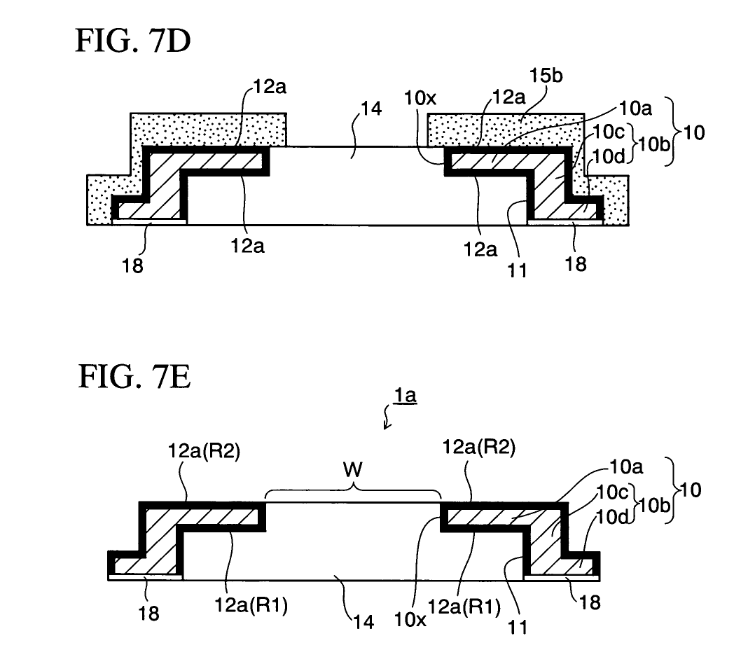

FIGS. 7A to 7E are sectional views showing a method of manufacturing an optical parts cap according to a second embodiment of the present invention. A feature of the second embodiment resides in that the darkening metal oxide layer is left on an outer surface of the metal frame and is utilized as the reflection preventing layer. In the second embodiment, detailed explanation of the same steps and the same elements as those in the first embodiment will be omitted herein.

First, as shown in FIG. 7A, the metal oxide layer 12a is formed on the whole surface of the metal frame 10 and darkened by the same method as the first embodiment. Then, the same structural body as that in FIG. 2C is formed by depositing the glass 14 to the housing portion 11 of the metal frame 10.

Then, as shown in FIG. 7B, a protection film 15b is pasted on the outer exposed portion except the lower surface of the upright frame portion 10b of the metal frame 10. Then, as shown in FIG. 7C, the metal oxide layer 12a is removed selectively from the lower surface of the upright frame portion 10b of the metal frame 10.

Then, as shown in FIG. 7D, the joining portion 18 is obtained by forming the Au layer on the lower surface of the upright frame portion 10b of the metal frame 10 by means of the electroplating or the electroless plating. Then, the protection film 15b is removed.

Accordingly, as shown in FIG. 7E, an optical parts cap la of the second embodiment is obtained. In the optical parts cap la of the second embodiment, the metal oxide layer 12a (kovar oxide layer) is formed on the inner surface and the outer surface of the metal frame 10 respectively and is darkened. As a result, the first and second reflection preventing layers R1, R2 are provided.

Like the first embodiment, the optical parts cap la of the second embodiment can be utilized as the cap for the DMD and the similar advantages to those in the first embodiment can be achieved. In addition, the metal oxide layer 12a formed simultaneously on the inner surface and the outer surface of the metal frame 10 can be utilized as the first and second reflection preventing layers R1, R2 as it is. Therefore, the manufacturing steps can be simplified rather than the first embodiment, and a lower cost can be attained.

1: An optical parts cap, comprising:
a metal frame including an upper frame portion in which an opening portion is provided in a center portion and an upright frame portion provided to be connected to a lower peripheral portion of the upper frame portion, the metal frame in which a housing portion is provided in an inside by the upright frame portion;
a reflection preventing layer formed on an outer surface and an inner surface of the metal frame respectively; and
a glass provided to the housing portion of the metal frame.

2: An optical parts cap according to claim 1, wherein a darkening process is applied to the outer surface of the metal frame to show black or gray, and
a metal oxide layer to show black or gray is formed on the inner surface of the metal frame.

3: An optical parts cap according to claim 1, wherein a metal oxide layer showing black or gray is formed on the outer surface and the inner surface of the metal frame.

4: An optical parts cap according to claim 2, wherein the metal frame is made of kovar, and the metal oxide layer is a kovar oxide layer.

5: An optical parts cap according to claim 2, wherein the darkening process including that a metal plating layer or an ink to show black or gray is formed.

6: An optical parts cap according to claim 1, wherein a joining portion is provided onto a lower surface of the upright frame portion and also the joining portion of the upright frame portion is joined to a substrate on which the optical parts is mounted, whereby the optical parts is hermetically sealed.

7: A method of manufacturing an optical parts cap, comprising the steps of:
forming a metal frame including an upper frame portion in which an opening portion is provided in a center portion and an upright frame portion provided to be connected to a lower peripheral portion of the upper frame portion, the metal frame in which a housing portion is provided in an inside by the upright frame portion, by processing a metal plate;
forming a metal oxide layer acting as a reflection preventing layer on an overall surface of the metal frame by oxidizing the metal frame;
depositing a glass to the housing portion of the metal frame;
removing selectively the metal oxide layer from an outer surface of the upper frame portion and an outer surface and a lower surface of the upright frame portion so as to leave the metal oxide layer on an inner surface of the metal frame as a first reflection preventing layer; and
forming a second reflection preventing layer on an outer surface of the metal frame, and forming a joining portion by applying a metal plating to a lower surface of the upright frame portion.

8: A method of manufacturing an optical parts cap, comprising the steps:
forming a metal frame including an upper frame portion in which an opening portion is provided in a center portion and an upright frame portion provided to be connected to a lower peripheral portion of the upper frame portion, the metal frame in which a housing portion is provided in an inside by the upright frame portion, by processing a metal plate;
forming a metal oxide layer acting as a reflection preventing layer on an overall surface of the metal frame by oxidizing the metal frame;
depositing a glass to the housing portion of the metal frame;
removing selectively the metal oxide layer from a lower surface of the upright frame portion; and
forming a joining portion by applying a metal plating to the lower surface of the upright frame portion.

9: A method of manufacturing an optical parts cap, according to claim 7, wherein the metal frame is made of kovar, and the metal oxide layer is a kovar oxide layer to show black or gray.

10: A method of manufacturing an optical parts cap, according to claim 7, wherein the step of forming the second reflection preventing layer is a step of forming a metal plating layer or an ink to show black or gray.

11: An optical parts cap according to claim 3, wherein the metal frame is made of kovar, and the metal oxide layer is a kovar oxide layer.

12: A method of manufacturing an optical parts cap, according to claim 8, wherein the metal frame is made of kovar, and the metal oxide layer is a kovar oxide layer to show black or gray.
